(19) United States
(12) Patent Application Publication
(10) Pub. No.: US 2013/0020574 A1
(43) Pub. Date: Jan. 24, 2013

(54) DISPLAY DEVICE AND METHOD OF MANUFACTURING THE SAME

(71) Applicant: Ichiro Sato, Osaka (JP)

(72) Inventor: Ichiro Sato, Osaka (JP)

(73) Assignee: Panasonic Corporation, Osaka (JP)

(21) Appl. No.: 13/620,651

(22) Filed: Sep. 14, 2012

Related U.S. Application Data
(63) Continuation of application No. PCT/JP2012/001591, filed on Mar. 8, 2012.

(30) Foreign Application Priority Data
Jul. 19, 2011 (JP) 2011-157440

(51) Int. Cl. H01L 33/16

(52) U.S. Cl. 257/59; 257/72; 438/34; 257/E33.053

(57) ABSTRACT

A display device includes a display element, a thin-film transistor for controlling light emission from the display element, and a signal line connected to the thin-film transistor. The thin-film transistor includes a gate electrode formed on an insulating substrate, a gate insulating film formed on the substrate so as to cover the gate electrode, a channel layer formed on the gate insulating film, and a source electrode and a drain electrode connected to the channel layer. A mounting terminal part of the signal line is formed by laminating a metal oxide layer on a copper layer; its cross section is trapezoidal; and the side surface and the periphery of the top surface of the mounting terminal part are covered with a protective film.

### TECHNICAL FIELD

The present invention relates to a display device including a thin-film transistor (hereinafter, abbreviated as “TFT”), such as an organic EL display device, and to a method of manufacturing such display devices.

### BACKGROUND ART

Conventionally, flat panel displays (FPD) have been positively developed, and there is known a display device including an organic electroluminescence (EL) element or liquid crystal display (LCD) element.

An LCD or organic EL display device uses an active matrix method that allows displaying any characters and figures with a high degree of accuracy using a large number of pixels. As an example of a driving circuit element by an active matrix method, a thin-film transistor method is known, where scan lines and signal lines are arranged in a matrix on a substrate with an insulating surface. Regions enclosed by scan lines and signal lines form pixels, each of which has a thin-film transistor disposed therein.

In recent years, there have been requests for upsizing and moving to finer resolution of display devices, revealing a disadvantage of delay in signal transmission at conductive materials of scan and signal lines. To solve this problem, using copper with lower resistance is devised instead of a conductive metal such as aluminum used as a conductive material.

Using copper as a conductive material requires antioxidation of copper. If a copper surface contacts oxygen or moisture in the air, an oxidized layer such as CuO and Cu₂O is formed on the surface. The oxidized layer does not become a passive state, and thus even the internal part is subject to oxidation, which increases the specific resistance of the copper as a conductive material, thereby degrading an advantage of copper of low resistance. Accordingly, some antioxidation layer is required so as not to expose a surface of copper wiring. To prevent oxidation on a copper surface, covering copper wiring with an insulating film (e.g. SiNₓ, SiOₓ, SiNO) used for manufacturing thin-film transistors is devised.

To insulate copper wiring from contacting the atmosphere and to protect the wiring from an etchant used for etching process, a metal oxide conductor is used such as indium tin oxide (hereinafter, abbreviated as “ITO”) and indium zinc oxide (hereinafter, abbreviated as “IZO”) instead of an insulating film.

Usually, such a metal oxide conductor is used as a transparent pixel electrode in a liquid crystal display device. A metal oxide conductor, not causing mutual atomic diffusion with copper, is also effective as a protective film for copper wiring, other than as a transparent pixel electrode. For example, if mounting terminal parts on which scan and signal lines formed of copper wiring and a driver circuit for instance are implemented are provided with a cap layer made of a metal oxide conductor, copper wiring is not oxidized due to oxygen or moisture in the atmosphere, and the specific resistance of copper wiring does not increase. Accordingly, if mounting terminal parts on which scan and signal lines formed of a copper thin film are implemented are provided with a cap layer made of a metal oxide conductor, it is an effective means for maintaining favorable connection with low contact resistance at mounting terminal parts. Further, if a contact hole is provided in an insulating film within a thin-film transistor substrate, and if connection parts between wirings through the contact hole are provided with a cap layer made of a metal oxide conductor, it is an effective means for maintaining favorable connection with low contact resistance at the connection parts.

In process of producing a thin-film transistor substrate, a metal thin film is formed over the entire surface of the substrate by sputtering for example. Then, metal conductor parts such as scan lines, signal lines, gate electrodes, source electrodes, drain electrodes, and capacitive electrodes are formed in given patterns by photolithography, where patterns are different depending on a part of copper wiring. To reduce the number of masks, a laminated structure of metal oxide conductor films is preferably pattern-formed on a copper thin film with the same resist mask in a one-time photolithography step for each wiring part.

Meanwhile, different etching liquids are used for between a metal oxide conductor such as ITO and copper, and thus a special etching liquid or a mixed solution of etching liquids for copper and a metal oxide conductor is used. For example, the following solution is devised (refer to patent literature 1 for instance). First, to etch a metal oxide conductor film, use a hydrochloric acid aqueous solution or the solution with nitric acid added thereto. To etch a copper thin film, use a solution containing ammonium persulfate solution or potassium peroxymonosulfate (KHSO₅) and fluorinated acid.

However, there have been requests for being able to easily manufacture display devices including low-resistance wiring made of copper, with long-lasting, high reliability.

### CITATION LIST

### Patent Literature

PTL 1 Japanese Patent Unexamined Publication No. 2001-196371

### SUMMARY OF THE INVENTION

A display device of the present invention includes a display element, a thin-film transistor for controlling light emission from the display element, and a signal line connected to the thin-film transistor. The thin-film transistor includes a gate electrode formed on an insulating substrate, a gate insulating film formed on the substrate so as to cover the gate electrode, a channel layer formed on the gate insulating film, and source and drain electrodes connected to the channel layer. A mounting terminal part of the signal line is formed by laminating a metal oxide layer on a copper layer; the cross section of the mounting terminal part is trapezoidal; and the side surface and the periphery of the top surface of the mounting terminal part are covered with a protective film.

A method of manufacturing display devices, of the present invention is that manufacturing the following display devices. That is, a display device includes a display element, a thin-film transistor for controlling light emission from the display element, and a signal line connected to the thin-film transistor. The thin-film transistor includes a gate electrode formed on an insulating substrate, a gate insulating film formed on the substrate so as to cover the gate electrode, a channel layer formed on the gate insulating film, and source and drain electrodes connected to the channel layer. In the method, the mounting terminal part of the signal line is formed by the following successive steps. That is, a metal oxide layer is laminated on a copper layer; then a resist mask is formed on the metal oxide layer; then the upper metal oxide layer is etched with the resist mask; then the lower metal copper layer is etched with the resist mask; then the upper metal oxide layer is etched again; then the cross section of the mounting terminal part is processed into a trapezoidal shape; and then the side surface and the periphery of the top surface of the mounting terminal part are covered with a protective film.

As described above, according to a copper wiring substrate for a thin-film transistor, a method of producing the substrate, and a display device including the substrates, of the present invention, a display device including low-resistance wiring made of copper, with a large size and finer resolution can be easily manufactured. Further, oxidation resistance and chemical resistance are achieved at inter-wiring connection parts through a mounting terminal part and a contact hole, to implement a display device with long-lasting and high reliability.

### BRIEF DESCRIPTION OF DRAWINGS

FIG. 1 is a partial cutaway perspective view of an organic EL display device as a display device according to an exemplary embodiment of the present invention.

FIG. 2 is a circuit configuration diagram of a pixel of the display device according to an exemplary embodiment of the present invention.

FIG. 3 is a sectional view showing the structure of a device composing a drive transistor in a pixel of the display device according to an exemplary embodiment of the present invention.

FIG. 4 is a sectional view showing the structure of a mounting terminal part in the display device according to an exemplary embodiment of the present invention.

FIG. 5A is a sectional view showing an example manufacturing process in a method of manufacturing thin-film transistors and accumulative capacitors, according to the embodiment of the present invention.

FIG. 5B is a sectional view showing an example manufacturing process in the method of manufacturing thin-film transistors and accumulative capacitors, according to the embodiment of the present invention.

FIG. 5C is a sectional view showing an example manufacturing process in the method of manufacturing thin-film transistors and accumulative capacitors, according to the embodiment of the present invention.

FIG. 5D is a sectional view showing an example manufacturing process in the method of manufacturing thin-film transistors and accumulative capacitors, according to the embodiment of the present invention.

FIG. 5E is a sectional view showing an example manufacturing process in the method of manufacturing thin-film transistors and accumulative capacitors, according to the embodiment of the present invention.

FIG. 5F is a sectional view showing an example manufacturing process in the method of manufacturing thin-film transistors and accumulative capacitors, according to the embodiment of the present invention.

FIG. 5G is a sectional view showing an example manufacturing process in the method of manufacturing thin-film transistors and accumulative capacitors, according to the embodiment of the present invention.

FIG. 5H is a sectional view showing an example manufacturing process in the method of manufacturing thin-film transistors and accumulative capacitors, according to the embodiment of the present invention.

FIG. 5I is a sectional view showing an example manufacturing process in the method of manufacturing thin-film transistors and accumulative capacitors, according to the embodiment of the present invention.

FIG. 5J is a sectional view showing an example manufacturing process in the method of manufacturing thin-film transistors and accumulative capacitors, according to the embodiment of the present invention.

FIG. 5K is a sectional view showing an example manufacturing process in the method of manufacturing thin-film transistors and accumulative capacitors, according to the embodiment of the present invention.

FIG. 5L is a sectional view showing an example manufacturing process in the method of manufacturing thin-film transistors and accumulative capacitors, according to the embodiment of the present invention.

FIG. 5M is a sectional view showing an example manufacturing process in the method of manufacturing thin-film transistors and accumulative capacitors, according to the embodiment of the present invention.

FIG. 5N is a sectional view showing an example manufacturing process in the method of manufacturing thin-film transistors and accumulative capacitors, according to the embodiment of the present invention.

FIG. 5O is a sectional view showing an example manufacturing process in the method of manufacturing thin-film transistors and accumulative capacitors, according to the embodiment of the present invention.

FIG. 5P is a sectional view showing an example manufacturing process in the method of manufacturing thin-film transistors and accumulative capacitors, according to the embodiment of the present invention.

FIG. 6A is a sectional view showing each step of a method of manufacturing mounting terminal parts, according to the embodiment of the present invention.

FIG. 6B is a sectional view showing each step of the method of manufacturing mounting terminal parts, according to the embodiment of the present invention.

FIG. 6C is a sectional view showing each step of the method of manufacturing mounting terminal parts, according to the embodiment of the present invention.

FIG. 6D is a sectional view showing each step of the method of manufacturing mounting terminal parts, according to the embodiment of the present invention.

FIG. 6E is a sectional view showing each step of the method of manufacturing mounting terminal parts, according to the embodiment of the present invention.

### DESCRIPTION OF EMBODIMENT EXEMPLARY EMBODIMENT

Hereinafter, a description is made of a display device, a thin-film transistor (TFT) used for the display device, and a method of manufacturing TFTs, according to an embodiment of the present invention with reference to the related drawings.

First, a description is made of a display device according to the embodiment of the present invention, taking an organic EL display device as an example.

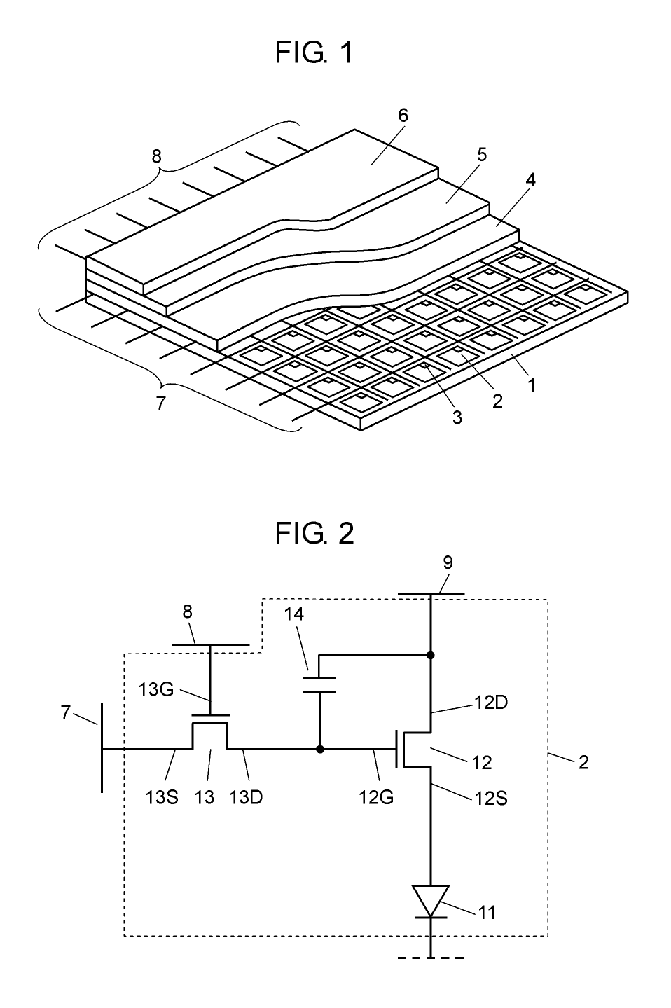

FIG. 1 is a partial cutaway perspective view of an organic EL display device as a display device according to the embodiment of the present invention, showing an outline structure of the organic EL display device. As shown in FIG. 1, the organic EL display device includes active matrix substrate 1; pixels 2 arranged in a matrix on active matrix substrate 1; pixel circuits 3 connected to pixels 2, arranged in an array on active matrix substrate 1; an EL element composed of electrode 4 as a positive electrode, organic EL layer 5, and electrode 6 as a negative electrode, each successively laminated on pixels 2 and pixel circuits 3; and a plurality of source wirings 7 and gate wirings 8 for connecting respective pixel circuits 3 to a control circuit. Organic EL layer 5 of the EL element is formed by successively laminating some layers such as an electron transfer layer, a light-emitting layer, and a positive hole transfer layer.

Next, a description is made of an example circuit configuration of pixel 2 using FIG. 2. FIG. 2 is a circuit configuration diagram of a pixel of a display device according to the embodiment of the present invention.

As shown in FIG. 2, pixel 2 includes organic EL element 11 as a display element; drive transistor 12 formed of a thin-film transistor for controlling the amount of light emitted from organic EL element 11; switching transistor 13 formed of a thin-film transistor for controlling timing (e.g. turning on and off) of driving organic EL element 11; and capacitor 14. Source electrode 13S of switching transistor 13 is connected to source wiring 7; gate electrode 13G, to gate wiring 8; and drain electrode 13D, to capacitor 14 and gate electrode 12G of drive transistor 12. Drain electrode 12D of drive transistor 12 is connected to power wiring 9; and source electrode 12S, to the anode of organic EL element 11.

As described above, the organic EL display device as a display device includes organic EL element 11 as a display element, a thin-film transistor for controlling light emission from the display element, and a signal line connected to the thin-film transistor.

In such a configuration, when a gate signal is input into gate wiring 8 and switching transistor 13 is turned on, a signal voltage corresponding to an image signal supplied through source wiring 7 is written into capacitor 14. The retaining voltage written into capacitor 14 is retained through one frame period.

The retaining voltage written into capacitor 14 changes the conductance of drive transistor 12 in an analog fashion to cause a drive current corresponding to the gradation in light emission to flow from the anode of organic EL element 11 to the cathode. The drive current running through the cathode causes organic EL element 11 to emit light, which is displayed as an image.

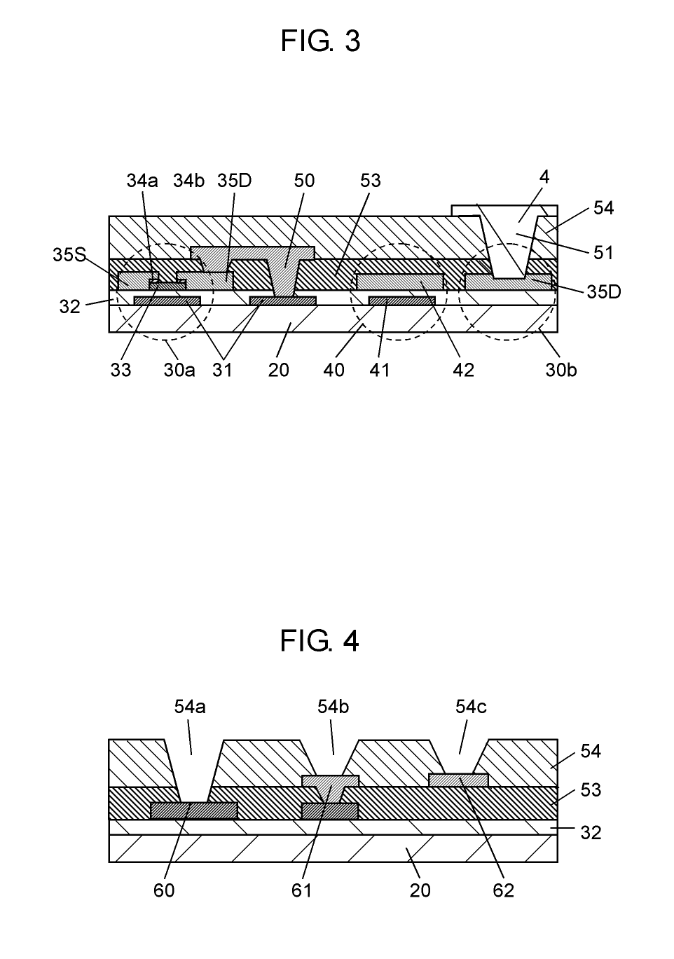

FIG. 3 is a sectional view showing the device structure in a pixel of an organic EL display device according to the embodiment of the present invention. FIG. 4 is a sectional view showing a configuration of the mounting terminal part of the organic EL display device.

First, as shown in FIG. 3, the part of the thin-film transistor of the organic EL display device has thin-film transistors 30a and 30b (collectively described as thin-film transistor 30) that become drive transistor 12 and switching transistor 13, and capacitor 40, formed on insulating substrate 20. In FIG. 3, only drain electrode 35D is shown for thin-film transistor 30b becoming drive transistor 12. The other components are the same as those of thin-film transistor 30a, and thus the following description takes thin-film transistor 30a as an example.

Thin-film transistor 30a is a bottom-gate, n-type thin-film transistor and is formed by successively laminating gate electrode 31 formed on insulating substrate 20, gate insulating film 32 formed on substrate 20 so as to cover gate electrode 31, channel layer 33 formed on gate insulating film 32, a pair of contact layers 34a and 34b separately formed on channel layer 33, and source electrode 35S and drain electrode 35D formed on the pair of contact layers 34a and 34b. Hence, source electrode 35S and drain electrode 35D are connected to channel layer 33.

Substrate 20 is an insulating substrate made of a glass (e.g. quartz glass) substrate. Here (not shown), to preventingress of impurities (e.g. sodium, phosphorus) contained in the substrate, the surface of substrate 20 may be coated with an undercoat film made of an insulating film (e.g. silicon nitride (SiNₓ) film, silicon oxide (SiOₓ) film).

Gate electrode 31 is an electrode made of molybdenum (Mo) for instance, pattern-formed in a strip shape on substrate 20 made of an insulating substrate. Gate electrode 31 may be made of a metal other than molybdenum (Mo), such as molybdenum tungsten (MoW). If the process of manufacturing thin-film transistor 30 includes a heating step, gate electrode 31 is preferably made of a high-melting-point metallic material resistant to heat alteration. In this embodiment, gate electrode 31 is made of molybdenum (Mo) with a film thickness of approximately 100 nm.

If copper is used as a gate electrode, heating process for such as crystallization is likely to cause copper to diffuse into a gate insulating film described later, and thus diffusion of copper needs to be reduced in forming a cap layer for instance. Meanwhile, in order to form a gate electrode and wiring simultaneously, the film thickness needs to be increased. A thick gate electrode impairs the coatability of the gate insulating film in forming a thin-film transistor, largely influencing yields in manufacturing. Hence, in this embodiment, gate electrodes and scan lines are formed in different steps. A gate electrode is formed of a high-melting point material with a film thickness as thin as less than or equal to 100 nm; a scan line, formed of copper with a film thickness as thick as greater than or equal to 200 nm. This results in low-resistance scan lines and heat-resistant gate electrodes.

Gate insulating film 32, which is formed so as to cover gate electrode 31, can be made of silicon dioxide (SiO₂) for instance. Otherwise, gate insulating film 32 can be formed of a silicon nitride (SiN) film or silicon oxynitride (SiON) film, or a laminated film from these films.

In this embodiment, a wiring layer formed on gate insulating film 32 is made of copper, and thus a part of gate insulating film 32 contacting a wiring material is preferably made of SiNₓ. Using SiNₓ reduces diffusion of copper. In this embodiment, gate insulating film 32 is made of SiNₓ with a film thickness of approximately 200 nm.

Channel layer 33 is pattern-formed in an island shape on gate insulating film 32 above gate electrode 31. Channel layer 33 is formed of a semiconductor film, and the on-current of the TFT can be raised by being formed of a semiconductor film with high mobility.

Channel layer 33 can be made of a crystalline silicon film containing crystalline silicon, an oxide semiconductor, or an organic semiconductor. A crystalline silicon film can be made of microcrystal silicon or polycrystalline silicon. Crystalline silicon can be formed by heat-treating (e.g. annealing) non-crystalline (amorphous) silicon for crystallization. A film thickness of approximately 30 to 160 nm allows retaining a required on-current while reducing an off-current. In this embodiment, channel layer 33 is made of a crystalline silicon film with a thickness of approximately 80 nm. In this embodiment, the crystal particle diameter of the crystalline silicon film is equal to or smaller than 1 μm. Channel layer 33 may be a mixed crystal of non-crystalline and crystalline structures.

Channel layer 33 is an undoped layer, where impurities are not intentionally added. However, impurities can be unintentionally mixed into a hydrogenated amorphous silicon film during the manufacturing process. For this reason, the silicon film as channel layer 33 preferably has an impurity concentration of equal to or less than 1×10¹⁸/cm³. Further, channel layer 33 preferably has a lowest possible impurity concentration, equal to or less than 1×10¹⁷/cm³. Here, a high impurity concentration of the silicon film as channel layer 33 unpreferably increases the off-current (Ioff).

The pair of contact layers 34a and 34b is formed of a non-crystalline silicon film containing impurities, on channel layer 33 spaced from each other, so as to cover channel layer 33 and its side surface. Contact layers 34a and 34b can be formed by adding n-type impurities (e.g. phosphorus (P)) into a non-crystalline silicon film with a thickness of approximately 10 to 50 nm. In this embodiment, film forming is made with a film thickness of 30 nm. The impurity concentration of contact layers 34a and 35b is preferably equal to or higher than 1×10²¹/cm³ and equal to or lower than 1×10²²/cm³, which is a typical value easily implemented when highly concentrated impurities are introduced into a silicon film.

The element of n-type impurities contained in contact layers 34a and 34b is not limited to phosphorus, but may be one, other than phosphorus, belonging to group 5. The type of impurities are not limited to n type, but may be p type containing a group 3 element such as boron (B). Although contact layers 35a and 35b may be formed of a single layer containing impurities with a certain concentration, a concentration changing from high to low toward channel layer 33 moderates the concentration of an electric field at the interface between contact layers 34a and 34b and channel layer 33, which preferably prevents a leak current during off.

Concretely, near source electrode 35S and drain electrode 35D, the impurity concentration of contact layers 34a and 34b is preferably in a high-concentration region of equal to or higher than 1×10²¹/cm³ and equal to or lower than 1×10²²/cm³; near channel layer 33, in a low-concentration region of equal to or lower than 5×10²⁰/cm³ (preferably equal to or higher than 1×10¹⁹/cm³ and equal to or lower than 1×10²⁰/cm³).

Source electrode 35S and drain electrode 35D are pattern-formed on contact layers 34a and 34b, respectively, spaced from each other. Source electrode 35S and drain electrode 35D are ohmic-connected to layers 34a and 34b, respectively, so that the side surfaces of the electrodes coincide with the layers. Source electrode 35S and drain electrode 35D are film-formed by sputtering for instance, of three metal layers of ITO, Cu, and Mo successively laminated in this order, with a film thickness of ITO of 100 nm; Cu, 300 nm; and Mo, 50 nm, so that the film thickness of the laminated film (i.e. three metal layers) is approximately between 200 and 1,000 nm.

Here, capacitor 40 is formed of electrode 41 (same as gate electrode 31 of thin-film transistor 30a), electrode 42 (same as source electrode 35S and drain electrode 35D), and gate insulating film 32 interposed between electrodes 41 and 42. Electrodes 41 and 42 of capacitor 40 are electrically connected to each electrode of thin-film transistors 30a and 30b through contact wiring part 50. Drain electrode 35D of thin-film transistor 30b is electrically connected to electrode 4 at the display element part shown in FIG. 1 through contact wiring part 51. Further, in order to insulate each electrode and contact wiring parts 50 and 51 from one another, interlayer insulating films 53 and 54 are formed made of silicon nitride (SiNₓ) film for instance.

Next, a description is made of the mounting terminal part shown in FIG. 4.

As shown in FIG. 4, mounting terminal parts 60, 61, and 62 are formed to connect signal lines connected to each electrode of the display device to an external electric circuit. Mounting terminal parts 60, 61, and 62 and the signal lines are formed of copper layers primarily containing copper, in the same way as source electrode 35S and drain electrode 35D of thin-film transistors 30a and 30b. Then, at the upper layer (cap layer) of the copper layer, a conductor is formed made of metal oxide such as indium tin oxide (ITO) and indium zinc oxide (IZO). At the lower layer (barrier layer) of the copper layer, a film is formed made of a single metal such as titanium (Ti), tantalum (Ta), molybdenum (Mo), and tungsten (W), or of two or more of these metals. The lower layer (barrier layer) of the copper layer is for preventing diffusion of copper when silicon is used for such as channel layer 33 and contact layer 34a. If the lower layer of the copper layer is made of a material same as that of the gate electrode, the manufacturing equipment and the material can be shared by each other, which is preferable in decreasing the manufacturing cost.

Mounting terminal parts 60, 61, and 62 are provided by forming interlayer insulating film 54 made of an insulating film such as a silicon nitride (SiNₓ) film with a thickness of 400 nm followed by forming openings 54a, 54b, and 54c in part of interlayer insulating film 54. Here, interlayer insulating films 53 and 54 may be made of any material as long as it achieves oxidation resistance and chemical resistance at the side surface of copper wiring, not limited to SiNₓ. Otherwise, a coated insulating film may be laminated for a thicker film, with SiNₓ used for the part directly contacting copper.

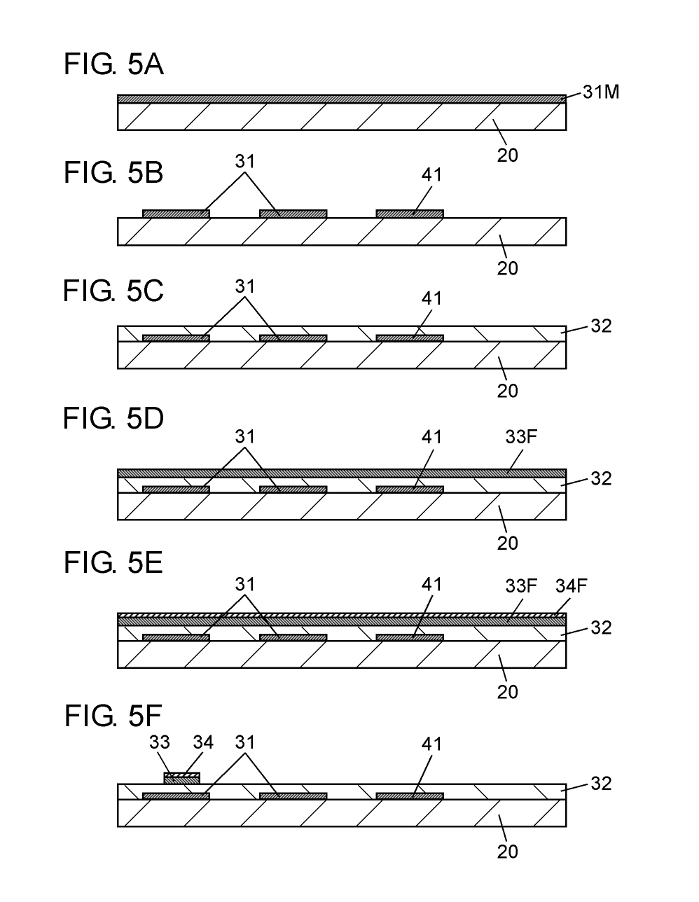

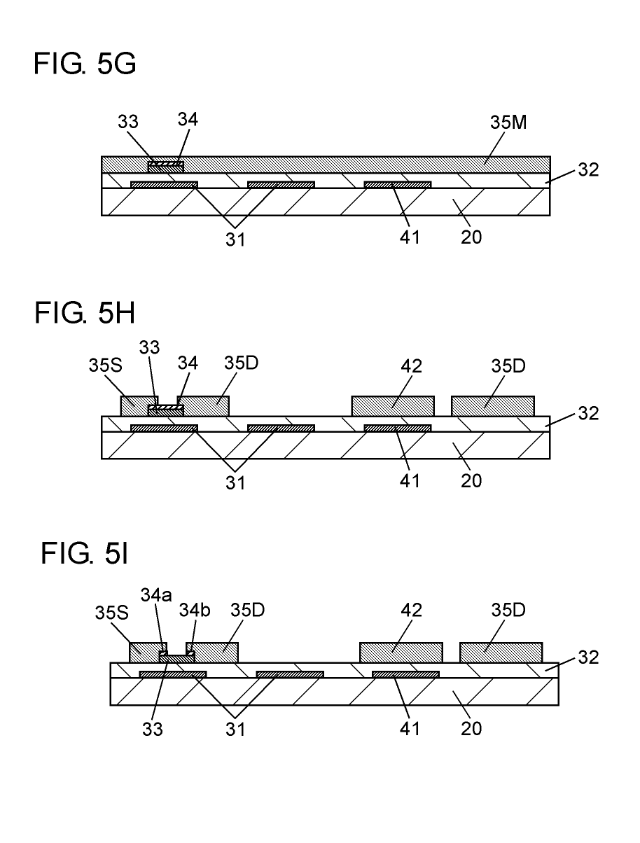

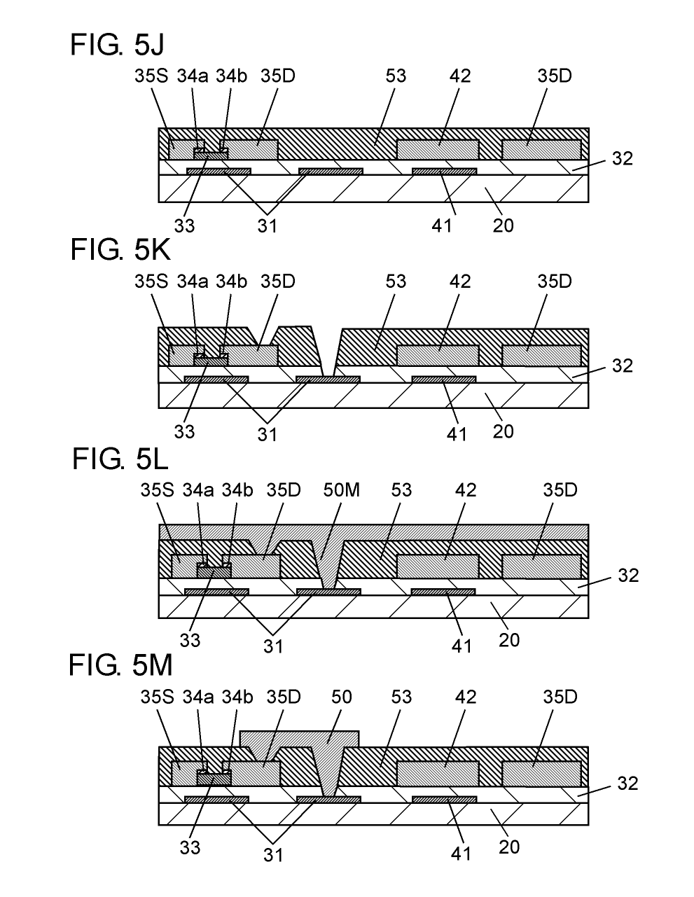

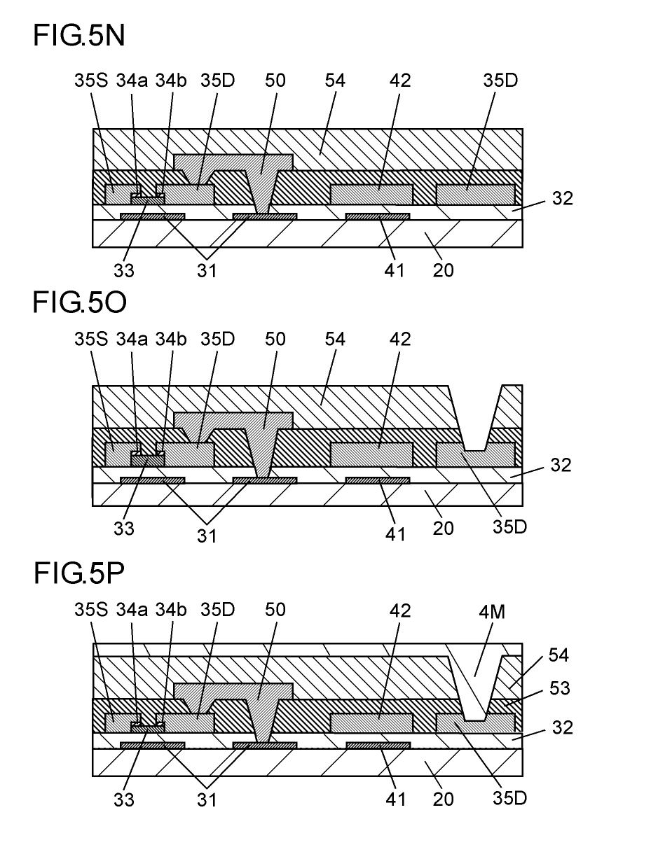

Next, a description is made of a method of manufacturing thin-film transistors and accumulative capacitors of the configuration shown in FIG. 3 using FIGS. 5A through 5P, which are sectional views showing an example manufacturing process for them.

First, as shown in FIG. 5A, gate metal film 31M made of such as molybdenum is film-formed on substrate 20 made of an insulating glass substrate by sputtering with a film thickness of approximately 100 nm. Here, an undercoat film may be formed on support substrate 20 before gate metal film 31M is formed.

Next, gate metal film 31M is applied with photolithography and wet etching to pattern gate metal film 31M to form gate electrode 31 and electrode 41 of a capacitor in a given shape as shown in FIG. 5B. After that, as shown in FIG. 5C, gate insulating film 32 made of a silicon oxide film is film-formed on substrate 20 with a film thickness of approximately 200 nm by plasma CVD (chemical vapor deposition) so as to cover gate electrode 31 and electrode 41.

Next, as shown in FIG. 5D, channel-layer-for-preformed film 33F is formed by crystalline silicon on gate insulating film 32 with a film thickness of approximately 30 nm. Film 33F can be formed by directly film-forming microcrystal silicon by CVD; or by film-forming non-crystalline silicon by plasma CVD followed by heat treatment with laser light or a lamp for crystallization.

Next, as shown in FIG. 5E, contact-layer-for-preformed film 34F made of non-crystalline silicon with phosphorus added thereinto as n-type impurities is film-formed, so as to cover channel-layer-for-preformed film 33F. After that, as shown in FIG. 5F, photolithography and dry etching are applied to simultaneously pattern contact-layer-for-preformed film 34F and channel-layer-for-preformed film 33F to form channel layer 33 and contact layer 34.

Next, as shown in FIG. 5G, source/drain metal film 35M is film-formed so as to cover contact layer 34 and channel layer 33. After that, as shown in FIG. 5H, photolithography and wet etching are applied to pattern source/drain metal film 35M to separately form source electrode 35S, drain electrode 35D, and electrode 41 of capacitor 40. Here, source/drain metal film 35M is etched by wet etching with a laminated structure of a metal oxide conductor film and copper. Further, as shown in FIG. 5I, contact layer 34 is patterned using the same pattern as in FIG. 5H by dry etching to separately form a pair of contact layers 34a and 34b in a given shape. Source electrode 35S is formed so as to cover the top surface of contact layer 34a and the side surface of channel layer 33. Drain electrode 35D is formed so as to cover the top surface of contact layer 34b and the side surface of channel layer 33.

Next, as shown in FIG. 5J, interlayer insulating film 53 made of a silicon nitride (SiNₓ) film is film-formed with a thickness of 400 nm so as to cover the entire surface of substrate 20. Successively, as shown in FIG. 5K, photolithography and wet etching (or dry etching) are applied to simultaneously form a contact hole to source electrode 35S, drain electrode 35D, and gate electrode 31 and an opening of a mounting terminal part (not shown), onto interlayer insulating film 53. The sectional view shown in FIG. 5K does not illustrate a contact hole to source electrode 35S, which is because the cross section where a contact hole to source electrode 35S is formed is different from that shown in FIG. 5K.

Next, as shown in FIG. 5L, wiring layer 50M is film-formed in a state covering the entire surface of substrate 20. After that, as shown in FIG. 5M, source electrode 35S, drain electrode 35D, and gate electrode 31 are connected to contact wiring part 50. Next, as shown in FIG. 5N, interlayer insulating film 54 is film-formed so as to cover the entire surface of substrate 20. After that, as shown in FIG. 5O, an opening is disposed in a part connecting to the mounting terminal part and electrode 4 for EL. Then, as shown in FIG. 5P, after electrode film 4M that becomes lower electrode 4 for EL is film-formed, photolithography and wet etching are applied to manufacture devices structured as in FIGS. 3 and 4.

In the present invention, mounting terminal parts 60, 61, and 62 of signal lines have a structure of a metal oxide (e.g. ITO) layer laminated on a copper layer; their cross sections are trapezoidal; and their side surfaces and the peripheries of their top surfaces are covered with a protective film.

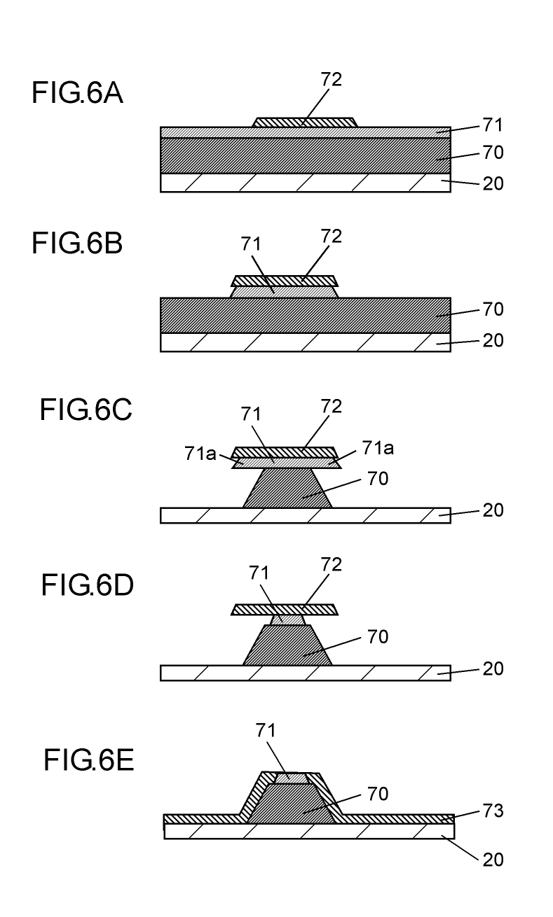

FIGS. 6A through 6E are sectional views showing each step of a method of manufacturing mounting terminal parts 60, 61, and 62, according to the embodiment of the present invention.

As shown in FIG. 6A, first, at the mounting terminal part 60, 61, and 62 of a signal line, copper layer 70 primarily containing copper is formed and metal oxide layer 71 made of ITO for instance is formed on substrate 20. After that, resist mask 72 is formed on the laminated film using a regular photolithography technique. Next, as shown in FIG. 6B, metal oxide layer 71 is wet etched with an oxalic acid aqueous solution. Next, as shown in FIG. 6C, wet etching is performed using resist mask 72 with a mixed acid of phosphoric acid, nitric acid, and acetic acid used for etching copper and a molybdenum thin film. After that, as shown in FIG. 6D, wet etching is performed using resist mask 72 with an oxalic acid aqueous solution to remove eave 71a of metal oxide layer 71. After that, resist mask 72 is removed to process the cross sections of mounting terminal parts 60, 61, and 62 into a trapezoidal shape. Then, as shown in FIG. 6E, the side surfaces and the peripheries of the top surfaces of mounting terminal parts 60, 61, and 62 are covered with protective film 73 to complete the process.

Consequently, in the present invention, mounting terminal parts 60, 61, and 62 of signal lines are formed in the following steps. That is, after forming a film by laminating a metal oxide layer on a copper layer, a resist mask is formed on the metal oxide layer. After that, first, the upper metal oxide layer is etched using the resist mask. Then, the lower copper layer is etched using the resist mask. After that, the upper metal oxide layer is etched again to process the cross section into a trapezoidal shape. After that, the side surfaces and the peripheries of the top surfaces of mounting terminal parts 60, 61, and 62 are covered with protective film 73. This eliminates eave 71a of metal oxide layer 71 and covers the side surfaces of the copper layer and the metal oxide layer with protective film 73 to prevent mounting terminal parts 60, 61, and 62 from corroding.

### INDUSTRIAL APPLICABILITY

As described above, the present invention is useful in producing a display device with high reliability.

### REFERENCE MARKS IN THE DRAWINGS

20 Substrate
30, 30a, 30b Thin-film transistor
31 Gate electrode
32 Gate insulating film
33 Channel layer
34, 34a, 34b Contact layer
35S Source electrode
35D Drain electrode
60, 61, 62 Mounting terminal part
70 Copper layer
71 Metal oxide layer
72 Resist mask
73 Protective film

1. A display device comprising a display element, a thin-film transistor for controlling light emission from the display element, and a signal line connected to the thin-film transistor, the thin-film transistor including:
a gate electrode disposed on an insulating substrate;
a gate insulating film disposed on the substrate so as to cover the gate electrode;
a channel layer disposed on the gate insulating film; and
a source electrode and a drain electrode connected to the channel layer,
wherein a mounting terminal part of the signal line is formed by laminating a metal oxide layer on a copper layer, a cross section of the mounting terminal part is trapezoidal, and a side surface and a periphery of a top surface of the mounting terminal part are covered with a protective film.

2. A method of manufacturing a display device,
the display device including:
a display element;
a thin-film transistor for controlling light emission from the display element; and
a signal line connected to the thin-film transistor,
the thin-film transistor including:
a gate electrode disposed on an insulating substrate;
a gate insulating film disposed on the substrate so as to cover the gate electrode;
a channel layer disposed on the gate insulating film;
a source electrode and a drain electrode connected to the channel layer,
wherein a mounting terminal part of the signal line is produced by the successive steps of:
forming a film by laminating a metal oxide layer on a copper layer;
forming a resist mask on the metal oxide layer;
then etching the upper metal oxide layer with the resist mask;
then etching the lower copper layer with the resist mask;
then etching the upper metal oxide layer again and processing a cross section of the mounting terminal part into a trapezoidal shape; and then
covering a side surface and a periphery of a top surface of the mounting terminal part with a protective film.
